(19) United States
(12) Patent Application Publication
(10) Pub. No.: US 2022/0149269 A1
(43) Pub. Date: May 12, 2022

(54) SPINTRONICS ELEMENT AND MAGNETIC MEMORY DEVICE

(71) Applicant: The University of Tokyo, Tokyo (JP)

(72) Inventors: Satoru Nakatsuji, Tokyo (JP); Yoshichika Otani, Tokyo (JP)

(21) Appl. No.: 17/430,115

(22) PCT Filed: Feb. 14, 2020
(86) PCT No.: PCT/JP2020/005901

§ 371 Date: Nov. 5, 2021

(30) Foreign Application Priority Data
Feb. 15, 2019 (JP) 2019-025853

(51) Int. Cl. H01L 43/04; H01L 27/22; H01L 43/06; H01L 43/08

(52) U.S. Cl. CPC H01L 43/04; H01L 43/08; H01L 43/06; H01L 27/222

(57) ABSTRACT

A spintronics element (100) includes an antiferromagnetic layer (20) and an MTJ element (30). The antiferromagnetic layer (20) is made of a canted antiferromagnet having a canted magnetic moment to exhibit a relatively tiny magnetization, and allows an electric current flowing in one direction (y-axis direction) parallel to an in-plane direction to induce spin accumulation in which spins of electrons are polarized parallel to or obliquely to an out-of-plane direction (z-axis direction). The MTJ element (30) is stacked on the antiferromagnetic layer (20), contains a ferromagnet with a magnetization (M11) aligned with the out-of-plane direction that is a stacking direction, and allows a spin current generated in the antiferromagnetic layer (20) to exert a spin-orbit torque on the magnetization (M11), thereby causing reversal of the magnetization (M11).

### TECHNICAL FIELD

The present invention relates to a spintronics element and a magnetic memory device.

### BACKGROUND ART

Magnetic random-access memories (MRAMs) have recently been studied as non-volatile memories. MRAMs currently in practical use are spin-transfer torque MRAMs (STT-MRAMs) utilizing spin-transfer torque (STT) (For example, see Patent Literature 1). In STT-MRAM, however, read and write operations share the same current path, which results in reducing writing endurance. In the meantime, spin-orbit torque MRAMs (SOT MRAMs) utilizing spin-orbit torque (SOT) have been studied and developed as promising MRAMs for providing significant improvement in writing endurance (For example, see Patent Literature 2).

Because SOT-MRAM with in-plane magnetization relies on magnetic shape anisotropy, a relatively large-sized memory cell is required. An anisotropic magnetic field needed for rotation of magnetization from an in-plane easy axis of magnetization to an in-plane hard axis of magnetization is about 0.1 T. On the other hand, saturation of magnetization in an out-of-plane direction requires a large barrier of about 1 T due to the magnetic shape anisotropy. Thus, the magnetization reversal occurs along the anisotropic path in SOT-MRAM with in-plane magnetization, which is highly likely to exhibit complicated precession of magnetization and cause write error. Furthermore, since an effectively large barrier is required for the magnetization reversal, a large electric current is necessary for the magnetization reversal accordingly.

In contrast, SOT-MRAM with perpendicular magnetization does not rely on the magnetic shape anisotropy and this makes it possible to achieve a relatively small-sized memory cell. A uniaxial anisotropy field resulting from interfacial magnetic anisotropy is about 0.1 T, and thus a barrier required for the magnetization reversal is small. Therefore, an electric current needed for the magnetization reversal is smaller than that in SOT-MRAM with in-plane magnetization, which leads to reduction in power consumption.

### CITATION LIST

### Patent Literature

Patent Literature 1: U.S. Pat. No. 8,981,503 B2
Patent Literature 2: JP 6,178,451 B1

### SUMMARY OF INVENTION

### Technical Problem

However, the conventional SOT-MRAM with perpendicular magnetization typically requires a unidirectional bias field to determine a rotational direction of magnetization. For this reason, there is a need to provide a mechanism for generating the bias field.

Here, when a ferromagnetic layer is adjacent to an antiferromagnetic layer having a magnetic order in which adjacent magnetic moments are oriented in the opposite directions, a unidirectional bias field is known to act on the ferromagnetic layer by the effect of exchange bias. By generating the bias field in an in-plane direction using the exchange bias, it is theoretically possible to reverse the perpendicular magnetization in the ferromagnetic layer due to a spin-orbit torque without requiring an external magnetic field (that is, at zero magnetic field).

Unfortunately, repeated reversal of magnetization in the ferromagnetic layer using the exchange bias results in reduction in the exchange bias field at the interface between the antiferromagnetic layer and the ferromagnetic layer due to a training effect. This hinders the magnetization reversal.

The present invention has been made in view of the foregoing, and an object of the invention is to provide a spintronics element and a magnetic memory device which enable reversal of perpendicular magnetization due to a spin-orbit torque at zero magnetic field without exchange bias.

### Solution to Problem

A spintronics element according to embodiments of the present invention includes an antiferromagnetic layer and a magneto-resistive element. The antiferromagnetic layer is made of a canted antiferromagnet having a canted magnetic moment to exhibit a relatively tiny magnetization, and is configured to allow an electric current flowing in one direction parallel to an in-plane direction of the antiferromagnetic layer to induce spin accumulation in which spins of electrons are polarized parallel to or obliquely to an out-of-plane direction of the antiferromagnetic layer. The magneto-resistive element is stacked on the antiferromagnetic layer, contains a ferromagnet with a perpendicular magnetization aligned with the out-of-plane direction that is a stacking direction, and is configured to allow a spin current generated in the antiferromagnetic layer to exert a spin-orbit torque on the perpendicular magnetization, thereby causing reversal of the perpendicular magnetization.

A magnetic memory device according to embodiments of the present invention includes a plurality of memory cells arranged in a matrix, and each of the plurality of memory cells includes the spintronics element described above and is connected to a bit line and a word line.

### Advantageous Effects of Invention

According to the present invention, spin accumulation is generated in an antiferromagnetic layer made of a canted antiferromagnet such that spins of electrons are spin-polarized parallel to or obliquely to an out-of-plane direction. This enables reversal of perpendicular magnetization in a ferromagnet stacked on the antiferromagnetic layer at zero magnetic field without exchange bias.

### BRIEF DESCRIPTION OF DRAWINGS

FIG. 1A is a schematic diagram illustrating a magnetic structure in real space and a fictitious magnetic field in momentum space for Mn₃Sn.

FIG. 1B is a schematic diagram illustrating a magnetic structure in the real space and a fictitious magnetic field in the momentum space for Mn₃Sn.

FIG. 2 is a graph illustrating magnetic-field dependence of Hall resistivity and magnetization of Mn₃Sn at room temperature.

FIG. 3 is a schematic diagram illustrating a conventional spin Hall effect in transition metal.

FIG. 4A is a schematic diagram illustrating a magnetic spin Hall effect in Mn₃Sn with the magnetic structure shown in FIG. 1A.

FIG. 4B is a schematic diagram illustrating a magnetic spin Hall effect in Mn₃Sn with the magnetic structure shown in FIG. 1B.

FIG. 5 is a graph illustrating conversion efficiency of electric currents into spin currents in transition metal (Pt, β-Ta, and β-W) and Mn₃Sn.

FIG. 6 is a schematic diagram illustrating reversal of perpendicular magnetization using a spin-orbit torque caused by the conventional spin Hall effect.

FIG. 7 is a schematic diagram illustrating reversal of perpendicular magnetization using a spin-orbit torque caused by the magnetic spin Hall effect according to embodiments of the present invention.

FIG. 8 is an exemplary circuit configuration diagram of a magnetic memory device according to the embodiments.

FIG. 9 is an exemplary circuit configuration diagram of each memory cell constituting the magnetic memory device shown in FIG. 8.

### DESCRIPTION OF EMBODIMENTS

Exemplary embodiments of the present invention will be described below with reference to the drawings. The same reference signs are used to designate the same or similar components throughout the drawings.

Ferromagnets exhibit a relatively large magnetization, and thus have been used extensively as key components of various devices including motors, power generators, magnetic sensors, and magnetic memories. Antiferromagnets, on the other hand, exhibit a very tiny magnetization, show an extremely small response, and are hard to control as opposed to ferromagnets, which leads to limited applications.

In recent years, spintronics for magnetic memories has required high density and high-speed processing. A memory cell with an antiferromagnetic component produces almost no stray fields because of a tiny magnetization described above. Therefore, antiferromagnets would be suitable for use in high-density magnetic memories. Moreover, antiferromagnets typically have a resonant frequency of about 1 THz which is several orders of magnitude higher than ferromagnets, and thus hold the promise of fast data processing.

The embodiments herein are directed to an example of application of antiferromagnets to magnetic memories. First, reference will be made to magnetic texture of Mn₃Sn as an example of antiferromagnets.

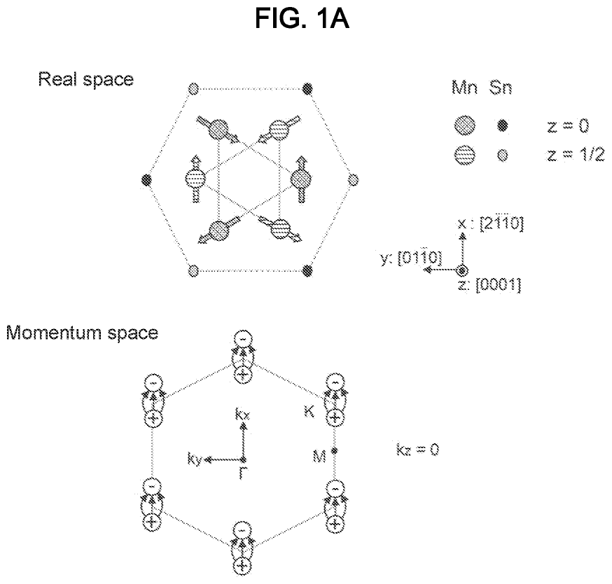

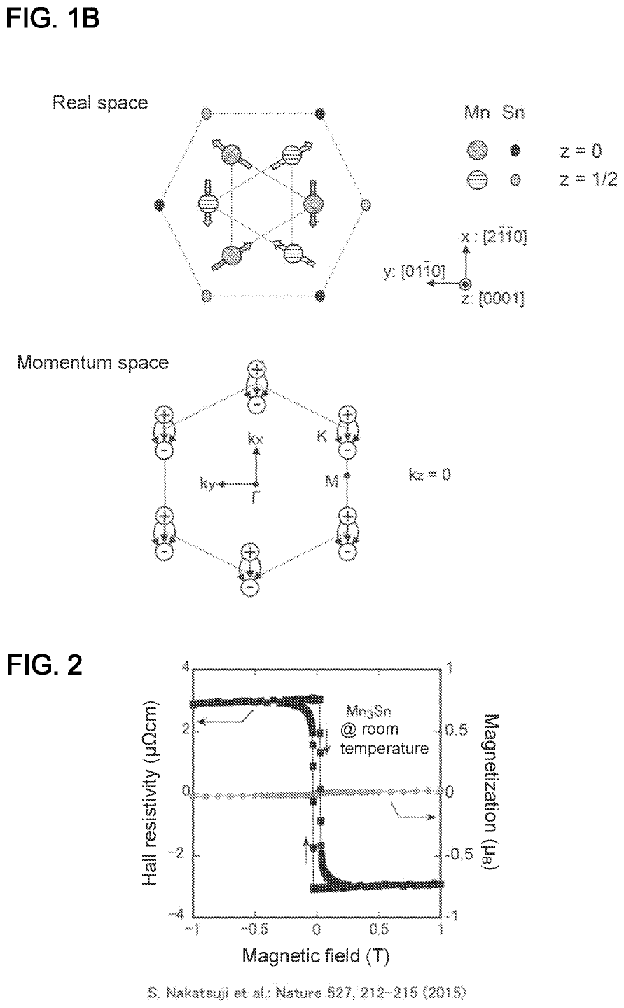

Mn₃Sn is an antiferromagnet having a crystal structure called kagome lattice that is a triangle-based lattice in which kagome lattice layers are stacked in [0001]direction (z-axis direction) in real space as shown in FIGS. 1A and 1B. Manganese (Mn) atoms located at vertices of kagome lattice have a non-collinear spin structure in which magnetic moments (directions of localized spins) are oblique to each other by 120 degrees at temperature of 420 K or below due to geometrical frustration. A unit of six spins consisting of two sets of three spins residing on a kagome lattice bilayer (z=0 plane and z=½ plane) forms a spin order called a cluster magnetic octupole depicted as hexagon.

Such a magnetic structure has orthorhombic symmetry, and one of the three magnetic moments of Mn atoms which are triangularly arranged is parallel to an easy axis of magnetization. The other two magnetic moments are canted with respect to the easy axis of magnetization, and thus are believed to induce a weak ferromagnetic moment. Such an antiferromagnet having a canted magnetic moment to exhibit a tiny magnetization is called a canted antiferromagnet.

As shown in FIG. 2, a negligibly small magnetization of several mμ_{B} is truly observed in Mn₃Sn at room temperature by applying an external magnetic field. This value is only one thousandth of magnetization of typical ferromagnets. On the other hand, as shown in FIG. 2, by measuring a Hall effect in Mn₃Sn at room temperature, magnetization reversal is observed at low magnetic field of several hundred gauss, and a rapid change in sign (positive or negative) of Hall resistivity is found accordingly. The change in Hall resistivity is found to be about 6 μΩcm. This indicates that the antiferromagnet with magnetization of several mμ_{B} exhibits a large response equivalent to that of ferromagnets, which leads to a feasible control of the antiferromagnet at room temperature and low magnetic field.

Recent studies have revealed that a large anomalous Hall effect in an antiferromagnet originates from a fictitious magnetic field (Berry curvature) in momentum space. In analogy with Gauss's law for electric charge in electromagnetics, a source and drain of the fictitious magnetic field corresponds to a positive magnetic charge (+) and negative magnetic charge (−), respectively.

In FIG. 1A, when an external magnetic field is applied in an x-axis positive direction in the real space, the magnetic structure in the real space shows that the spins of Mn₃Sn cancel out each other, whereas in the momentum space (kx, ky, kz), the positive magnetic charge (+) and the negative magnetic charge (−) form a dipole with K point between these magnetic charges so that the dipoles are ferromagnetically arranged on a boundary of hexagonal Brillouin zone. When the direction of this external magnetic field is reversed, the magnetic structure in the real space and the fictitious magnetic field in the momentum space for Mn₃Sn are also reversed as shown in FIG. 1B. An arrangement of the dipoles in the momentum space shown in FIGS. 1A and 1B indicates that a magnetic order of Mn₃Sn macroscopically breaks time-reversal symmetry in analogy with a spin arrangement of ferromagnets in the real space.

Recent researches have revealed that the cluster magnetic octupole shown in FIGS. 1A and 1B can be manipulated by applying an external magnetic field, and a large fictitious magnetic field equivalent to an external magnetic field of 100 T or more can be reversed along with the reversal of the cluster magnetic octupole, which makes it possible to control transport phenomena such as the anomalous Hall effect.

By utilizing such a large fictitious magnetic field in the momentum space, a spin Hall effect, which converts an electric current to a spin current, could appear in an antiferromagnet as will be described later.

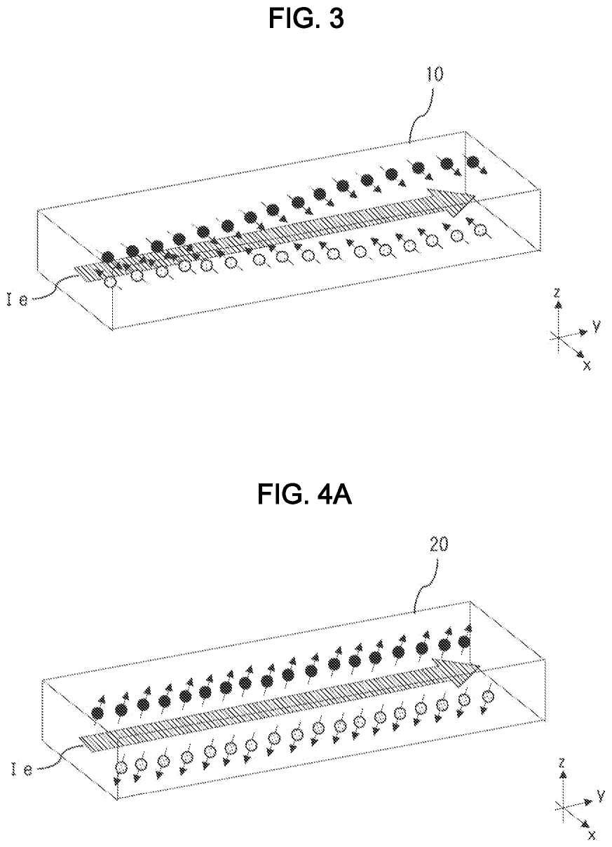

The spin Hall effect is a phenomenon in which an electric current flowing through a non-magnetic sample or the like induces a spin current in a direction orthogonal to the electric current, by scattering of electrons due to spin-orbit interaction. FIG. 3 is a schematic diagram illustrating a conventional spin Hall effect in a transition metal layer 10. The transition metal layer 10 is made of a transition metal which exhibits a strong spin-orbit interaction, such as platinum (Pt), tantalum (Ta), and tungsten (W), and has a board shape extending in an x-y plane, elongated in one direction (y axis direction).

As shown in FIG. 3, when an electron current Ie flows through the transition metal layer 10 in a y-axis positive direction (i.e., when an electric current flows in a y-axis negative direction), spin-polarized electrons with an x-axis positive polarization and spin-polarized electrons with an x-axis negative polarization are scattered in a z-axis positive direction and a z-axis negative direction, respectively, and thus are accumulated on an upper surface (on the z-axis positive direction side) and a lower surface (on the z-axis negative direction side) of the transition metal layer 10, respectively. This phenomenon is called spin accumulation. In this manner, a spin current is generated in an out-of-plane direction (z-axis direction), which induces a spin-orbit torque by the spin-polarized electrons with an in-plane polarization.

The embodiments herein are directed to a spin Hall effect which appears in an antiferromagnet (hereinafter referred to as a “magnetic spin Hall effect”).

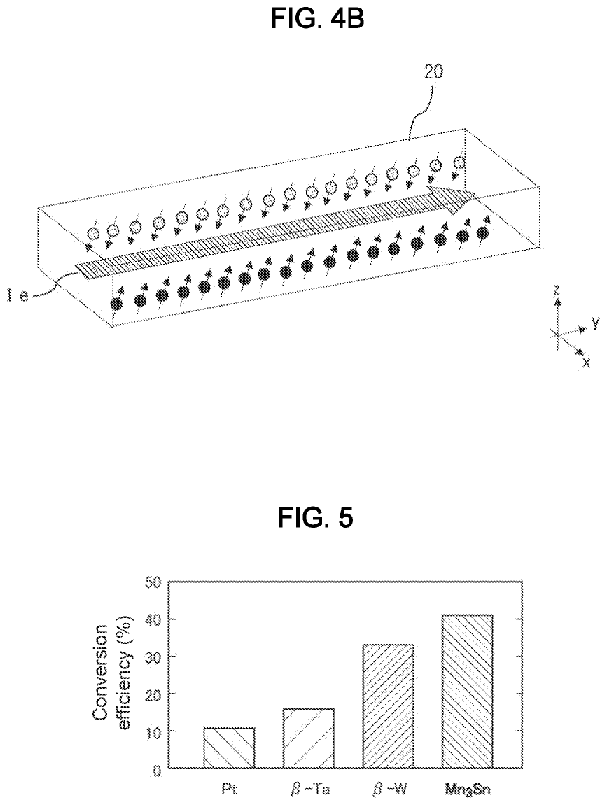

FIG. 4A illustrates the magnetic spin Hall effect in Mn₃Sn with the magnetic structure shown in FIG. 1A, and FIG. 4B illustrates the magnetic spin Hall effect in Mn₃Sn with the magnetic structure shown in FIG. 1B. In FIGS. 4A and 4B, an antiferromagnetic layer 20 is made of Mn₃Sn and has a board shape extending in an x-y plane, elongated in one direction (y axis direction).

As for Mn₃Sn with the magnetic structure shown in FIG. 1A, when an electron current Ie flows through the antiferromagnetic layer 20 in the y-axis positive direction (i.e., when an electric current flows in the y-axis negative direction), a non-zero spin polarization component appears in the out-of-plane direction (z-axis direction) of the antiferromagnetic layer 20. Specifically, spin-polarized electrons with polarization parallel to or oblique to the out-of-plane direction of the antiferromagnetic layer 20 are scattered toward an upper surface (on the z-axis positive direction side) and a lower surface (on the z-axis negative direction side) of the antiferromagnetic layer 20, thereby generating spin accumulation with non-zero vertical polarization components on the surfaces. In the spin accumulation, the spin polarization directions on the upper and lower surfaces of the antiferromagnetic layer 20 are opposite to each other.

As described above, when the external magnetic field applied to Mn₃Sn shown in FIG. 1A is reversed, the magnetic structure in the real space and the fictitious magnetic field in the momentum space are also reversed as shown in FIG. 1B. In a case where Mn₃Sn of the antiferromagnetic layer 20 has the magnetic structure shown in FIG. 1B, when the electric current flows through the antiferromagnetic layer 20 in the same direction as that in FIG. 4A, the spin polarization directions on the upper and lower surfaces of the antiferromagnetic layer 20 are reversed as shown in FIG. 4B.

Since a change in the spin arrangement of Mn₃Sn by applying the external magnetic field enables the control of the spin polarization direction in the spin accumulation on the surfaces, a direction and magnitude of the spin-orbit torque can also be changed. Alternatively, reversal of the direction of the electric current flowing through the antiferromagnetic layer 20 (changing from the y-axis negative direction to the y-axis positive direction, or the other way around) can also cause the reversal of the spin polarization direction, thereby changing the direction of the spin-orbit torque.

As shown in FIG. 5, a measurement of the spin current generated by the magnetic spin Hall effect in Mn₃Sn indicates that a conversion efficiency of the electric current into the spin current (spin Hall angle) in Mn₃Sn is higher than that in Pt, β-Ta, and β-W, all of which exhibit a strong spin-orbit interaction.

As described above, Mn₃Sn enables a change in the direction and magnitude of the spin-orbit torque and shows a high conversion efficiency, which leads to generation of a novel spin-orbit torque different from the conventional spin-orbit torque in a transition metal, as will be described later.

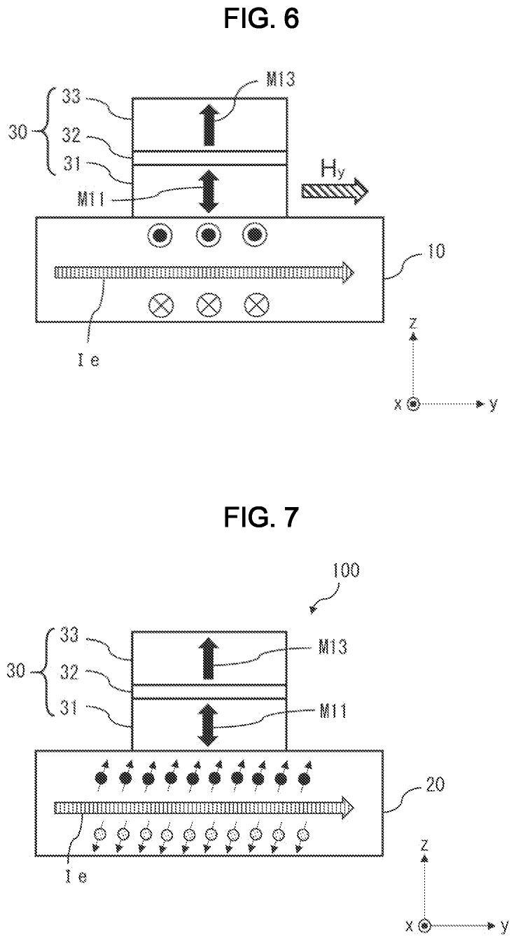

Next, reversal of perpendicular magnetization in SOT-MRAM will be described with reference to FIGS. 6 and 7.

As shown in FIG. 6, each memory cell of the conventional SOT-MRAM includes a spintronics element composed of the transition metal layer 10 and a magnetic tunnel junction element (MTJ element) 30 as a magneto-resistive element stacked on the transition metal layer 10. The MTJ element 30 includes a free layer 31 made of a ferromagnet such as CoFeB with a reversible magnetization M11 aligned with the out-of-plane direction (z-axis direction), a barrier layer 32 made of an insulating material such as MgO, and a fixed layer 33 made of a ferromagnet such as CoFeB with a fixed magnetization M13 aligned with the out-of-plane direction (z-axis positive direction in FIG. 6). The free layer 31, the barrier layer 32, and the fixed layer 33 are stacked on the transition metal layer 10 in this order, and a stacking direction corresponds to the out-of-plane direction. The MTJ element 30 is in a low-resistance state when the magnetization M13 of the fixed layer 33 and the magnetization M11 of the free layer 31 are in the same direction (parallel state), and the MTJ element 30 is in a high-resistance state when the magnetization M13 of the fixed layer 33 and the magnetization M11 of the free layer 31 are in the opposite directions (anti-parallel state).

As described above, an electric current flowing through the transition metal layer 10 in a longitudinal direction (y-axis direction) induces a spin current with in-plane spin polarization (x-axis direction) flowing in the out-of-plane direction (z-axis direction). Here, in order to determine a rotational direction of the magnetization M11 of the free layer 31, a unidirectional bias field Hy needs to be applied to slightly tilt the magnetization M1 to the direction of the bias field Hy. FIG. 6 shows an example of the bias field Hy being applied in the y-axis positive direction. The bias field Hy is defined as either a magnetic field generated by a magnet or an electrically generated external magnetic field. The spin-polarized electrons with in-plane polarization on the interface with the MTJ element 30 exert the spin-orbit torque on the magnetization M11 of the free layer 31. This causes the rotation of the magnetization M11 in the rotational direction determined by the bias field Hy, leading to the reversal of the magnetization M11.

Each memory cell of an SOT-MRAM according to the embodiments includes a spintronics element 100 shown in FIG. 7. As shown in FIG. 7, the spintronics element 100 includes the antiferromagnetic layer 20 and the MTJ element 30 stacked on the antiferromagnetic layer 20. As described above, when an electric current flows through the antiferromagnetic layer 20 in a longitudinal direction (y-axis direction), the spin-polarized electrons with polarization parallel to or oblique to the out-of-plane direction (z-axis direction) of the antiferromagnetic layer 20 are scattered toward the upper surface (on the z-axis positive direction side) and the lower surface (on the z-axis negative direction side) of the antiferromagnetic layer 20, thereby generating spin accumulation on each surface.

The spin-polarized electrons with polarization parallel to or oblique to the out-of-plane direction on the interface with the MTJ element 30 exert the spin-orbit torque on the magnetization M11 of the free layer 31. Since the spin polarization is oriented in the out-of-plane direction or oblique to the out-of-plane direction, the magnetization M11 rotates by experiencing the torque due to the spin polarization, which enables the magnetization reversal. The reversal of the direction of the electric current flowing through the antiferromagnetic layer 20 causes the reversal of the spin polarization direction, thereby changing the direction of the spin-orbit torque.

Specifically, when the magnetization M11 is oriented in the z-axis negative direction, the generation of the spin current with a non-zero spin polarization component in the z-axis positive direction on the interface (upper surface) of the antiferromagnetic layer 20 allows the magnetization M11 to rotate by experiencing the torque based on the spin accumulation, enabling the reversal of the magnetization M11 in the z-axis positive direction. When the magnetization M11 is oriented in the z-axis positive direction, the generation of the spin current with a non-zero spin polarization component in the z-axis negative direction on the interface (upper surface) of the antiferromagnetic layer 20 allows the magnetization M11 to rotate by experiencing the torque based on the spin accumulation, enabling the reversal of the magnetization M11 in the z-axis negative direction.

Since the spintronics element 100 of the embodiments is capable of generating, by the magnetic spin Hall effect, the spin accumulation with spin polarization parallel to or oblique to the out-of-plane direction, the spin current can be coupled to the magnetization M11 (perpendicular magnetization) without the conventionally required bias field Hy. In other words, the perpendicular magnetization of the MTJ element 30 can be reversed solely by the spin current. It is therefore possible to achieve the reversal of perpendicular magnetization at zero magnetic field without the necessity of exchange bias, which makes it possible to provide SOT-MRAMs with high resistance to write error and high writing endurance.

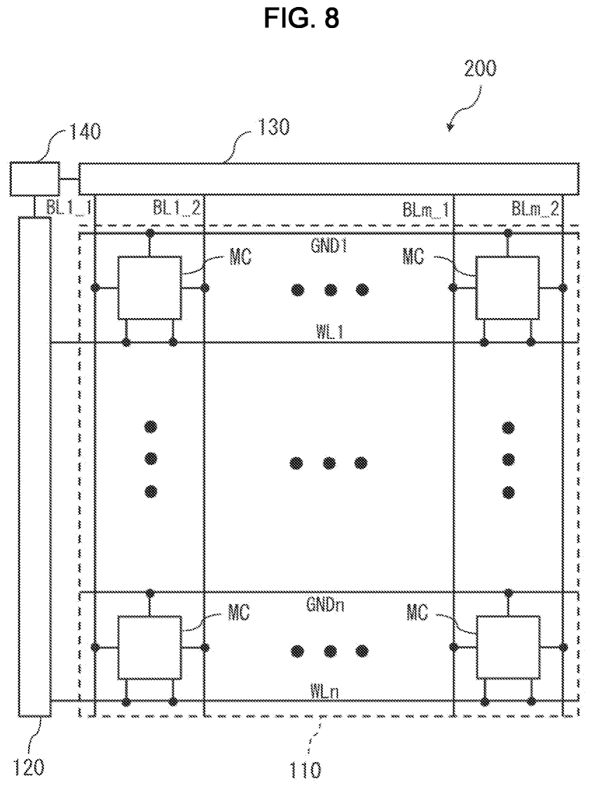

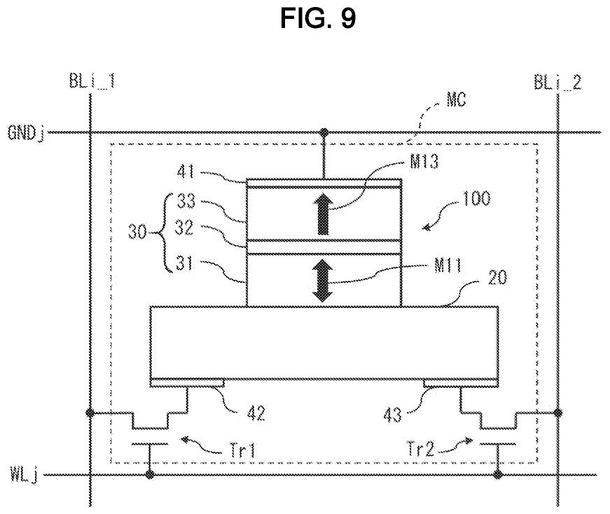

Next, a magnetic memory device 200 corresponding to the SOT-MRAM of the embodiments will be described with reference to FIGS. 8 and 9.

As shown in FIG. 8, the magnetic memory device 200 includes a memory cell array 110, an X driver 120, a Y driver 130, and a controller 140. The X driver 120 and the Y driver 130 are connected to the memory cell array 110, and the controller 140 is connected to the X driver 120 and the Y driver 130.

The memory cell array 110 includes a plurality of memory cells MCs which are arranged in an m×n matrix. Each memory cell MC is connected to a first bit line BLi_1 and a second bit line BLi_2 (i=1, 2, . . . , m) and further connected to a word line WLj and a ground line GNDj (j=1, 2, . . . , n).

The X driver 120 is connected to a plurality of word lines WLj (j=1, 2, . . . , n) and drives the word line WLj which is an access target to an active level (e.g., H level) under control of the controller 140. The ground line GNDj is set to a ground voltage. The ground line GNDj may be set to a reference voltage other than the ground voltage.

The Y driver 130 is connected to a plurality of pairs of bit lines (the first bit line BLi_1 and the second bit line BLi_2) (i=1, 2, . . . , m) and sets voltage levels (H level or L level) of the first bit line BLi_1 and the second bit line BLi_2 which are access targets under control of the controller 140.

As shown in FIG. 9, each memory cell MC is a three-terminal device including a first terminal 41 connected to the fixed layer 33 of the MTJ element 30, a second terminal 42 connected to a one end portion of the antiferromagnetic layer 20, and a third terminal 43 connected to the other end portion of the antiferromagnetic layer 20. Each memory cell MC further include transistors Tr1 and Tr2 connected to the second terminal 42 and the third terminal 43, respectively. In the embodiments, each of the transistors Tr1 and Tr2 is defined as an N-channel metal oxide semiconductor (NMOS) transistor.

The first terminal 41, the second terminal 42, and the third terminal 43 are connected to the ground line GNDj, a drain of the transistor Tr1, and a drain of the transistor Tr2, respectively. Gates of the transistors Tr1 and Tr2 are connected to the word line WLj. Sources of the transistors Tr1 and Tr2 are connected to the first bit line BLi_1 and the second bit line BLi_2, respectively.

Next, reference will be made to writing and reading data to and from the MTJ element 30.

Data “0” and “1” are assigned to resistance states of the MTJ element 30 to represent 1-bit data. In the embodiments, “0” and “1” are assigned to the low-resistance state and the high-resistance state, respectively, but the data assignment in the MTJ element 30 can be reversed.

Suppose that the MTJ element 30 of the memory cell MC located in i-th row and j-th column is in a low-resistance state storing data “0,” or in other words, the magnetization M13 of the fixed layer 33 and the magnetization M11 of the free layer 31 are in the same direction. In order to write data “1” to the memory cell MC in this low-resistance state, the word line WLj is set to H level, the first bit line BLi_1 is set to H level, and the second bit line BLi_2 is set to L level. With these settings, the transistors Tr1 and Tr2 are turned on, and a write current flows through the antiferromagnetic layer 20 from the first bit line BLi_1 side to the second bit line BLi_2 side, causing generation of a spin current in the out-of-plane direction by the magnetic spin Hall effect. The spin current exerts a spin-orbit torque on the magnetization M11 to reverse the magnetization M11, causing data “1” to be written to the memory cell MC.

Suppose that the MTJ element 30 of the memory cell MC located in i-th row and j-th column is in a high-resistance state storing data “1,” or in other words, the magnetization M13 of the fixed layer 33 and the magnetization M11 of the free layer 31 are in the opposite directions. In order to write data “0” to the memory cell MC in this high-resistance state, the word line WLj is set to H level, the first bit line BLi_1 is set to L level, and the second bit line BLi_2 is set to H level. With these settings, the transistors Tr1 and Tr2 are turned on, and a write current flows through the antiferromagnetic layer 20 from the second bit line BLi_2 side to the first bit line BLi_1 side, causing generation of a spin current in the out-of-plane direction by the magnetic spin Hall effect. The spin current exerts a spin-orbit torque on the magnetization M11 to reverse the magnetization M11, causing data “0” to be written to the memory cell MC.

When the write current for writing data “0” flows through the antiferromagnetic layer 20 in a case where the MTJ element 30 stores data “0” and when the write current for writing data “1” flows through the antiferromagnetic layer 20 in a case where the MTJ element 30 stores data “1,” an angle between the direction of the magnetization M11 and the spin polarization direction on the interface of the antiferromagnetic layer 20 is small, and thus a small spin-orbit torque is exerted on the magnetization M11. This results in no reversal of the magnetization M11 and no writing of data.

In order to read data stored in the memory cell MC located in i-th row and j-th column, the word line WLj is set to H level, one of the first bit line BLi_1 and the second bit line BLi_2 is set to H level, and the other is set to an open state. With these settings, the transistors Tr1 and Tr2 are turned on, and a read current flows from the first bit line BLi_1 or the second bit line BLi_2 which is in H level, into the ground line GNDj through the antiferromagnetic layer 20, the free layer 31, the barrier layer 32, the fixed layer 33, and the first terminal 41. By measuring the magnitude of the read current, the resistance state of the MTJ element 30, i.e., data stored in the MTJ element 30 can be obtained.

The present invention is not limited to the above embodiments, and many modifications and variations will be apparent to those of ordinary skill in the art without departing from the scope of the present invention.

For example, although the above embodiments are directed to Mn₃Sn as an example of canted antiferromagnets exhibiting a magnetic spin Hall effect, typical substances that can be employed herein include canted antiferromagnets with composite formula Mn₃X (where X is Sn, Ge, Ga, Rh, Pt, Ir, or the like) exhibiting a large anomalous Hall effect. Another candidate substances for the antiferromagnets exhibiting a magnetic spin Hall effect include gamma-phase of Mn₁₋ₓTrₓ (where Tr is Ni, Fe, Cu, Ru, Pd, Ir, Rh, Pd, or Pt).

Furthermore, as an example of the magneto-resistive element, the above embodiments are directed to the MTJ element 30 stacked on the antiferromagnetic layer 20, but any other such magneto-resistive element may also be employed.

### REFERENCE SIGNS LIST

20 Antiferromagnetic Layer
30 MTJ element
31 Free Layer
32 Barrier Layer
33 Fixed Layer
100 Spintronics Element
110 Memory Cell Array
120 X driver
130 Y driver
140 Controller
200 Magnetic Memory Device
BLi_1 First Bit Line
BLi_2 Second Bit Line
GNDj Ground Line
MC Memory Cell
Tr1, Tr2 Transistor
WLj Word Line

1. A spintronics element comprising:
an antiferromagnetic layer made of a canted antiferromagnet having a canted magnetic moment, and configured to allow an electric current flowing in one direction parallel to an in-plane direction of the antiferromagnetic layer to induce spin accumulation in which spins of electrons are polarized parallel to or obliquely to an out-of-plane direction of the antiferromagnetic layer; and
a magneto-resistive element stacked on the antiferromagnetic layer and containing a ferromagnet with a perpendicular magnetization aligned with the out-of-plane direction that is a stacking direction, the magneto-resistive element being configured to allow a spin current generated in the antiferromagnetic layer to exert a spin-orbit torque on the perpendicular magnetization, thereby causing reversal of the perpendicular magnetization.

2. The spintronics element according to claim 1, wherein
the canted antiferromagnet has a spin order of a cluster magnetic octupole.

3. The spintronics element according to claim 1, wherein
applying a magnetic field to the antiferromagnetic layer is configured to cause a change in a magnetic structure of the canted antiferromagnet and a change in a polarization direction of the spins in the spin current.

4. The spintronics element according to claim 1, wherein
in the antiferromagnetic layer, a polarization direction of the spins in the spin current is configured to change depending on a direction of the electric current flowing parallel to the in-plane direction.

5. The spintronics element according to claim 1, wherein
the canted antiferromagnet exhibits an anomalous Hall effect.

6. The spintronics element according to claim 1, wherein
a composition formula of the canted antiferromagnet is expressed as Mn₃X where X is Sn, Ge, Ga, Rh, Pt, or Ir.

7. The spintronics element according to claim 1, wherein
the magneto-resistive element comprises:
a ferromagnetic free layer stacked on the antiferromagnetic layer and allowing the reversal of the perpendicular magnetization;
an insulating barrier layer stacked on the ferromagnetic free layer; and
a ferromagnetic fixed layer stacked on the insulating barrier layer and having a fixed magnetization aligned with the out-of-plane direction.

8. A magnetic memory device comprising a plurality of memory cells arranged in a matrix, wherein
each of the plurality of memory cells includes the spintronics element according to claim 1 and is connected to a bit line and a word line.
